(19) United States
(12) Patent Application Publication
(10) Pub. No.: US 2013/0092528 A1
(43) Pub. Date: Apr. 18, 2013

(54) FILM-FORMING DEVICE AND FILM-FORMING METHOD

(71) Applicants: Yoshinori Fujii, Susono-shi (JP); Shinya Nakamura, Susono-shi (JP)

(72) Inventors: Yoshinori Fujii, Susono-shi (JP); Shinya Nakamura, Susono-shi (JP)

(73) Assignee: ULVAC, INC., Chigasaki-shi (JP)

(21) Appl. No.: 13/581,648

(22) PCT Filed: Jun. 30, 2011
(86) PCT No.: PCT/JP2011/064998

§ 371 Date: Sep. 6, 2012

(30) Foreign Application Priority Data
Jun. 30, 2010 (JP) 2010-149321

(51) Int. Cl. C23C 14/50

(52) U.S. Cl. CPC C23C 14/505
USPC 204/192.12; 204/298.12

(57) ABSTRACT

A film-forming device is provided, including: a chamber in which a substrate is disposed; a target, disposed within the chamber, which contains a material from which a film is formed; a substrate-supporting table disposed inside the chamber; driving unit that rotates the substrate-supporting table; a sputtering cathode that causes sputtered particles to be incident on the substrate from an oblique direction; and a control unit that controls the driving unit by setting a rotation period so that a sputtering film formation time required to form a film having a desired thickness is an integer multiple of a rotation period of the substrate-supporting table.

### CROSS REFERENCE TO RELATED APPLICATIONS

This is the U.S. National Phase Application under 35 U.S.C. §371 of International Patent Application No. PCT/JP2011/064998 filed Jun. 30, 2011, which designated the United States and was published in a language other than English, which claims the benefit of Japanese Patent Application No. 2010-149321, filed on Jun. 30, 2010, both of them are incorporated by reference herein.

### FIELD OF THE INVENTION

The present invention relates to a film-forming device and a film-forming method for forming a film on the surface of a substrate, and particularly to a film-forming device in which a plurality of sputtering cathodes are provided, and a film-forming method making use of the device.

### BACKGROUND

Conventionally, for example, film-forming devices (hereinafter, called “sputtering devices”) making use of a sputtering method have been used for a film-forming process in the manufacturing of semiconductor devices. Among those, as a sputtering device in which continuous film formation and multi-target sputtering can be performed without breaking a vacuum within the same device, a multi-target sputtering device is known. The multi-target sputtering device is a sputtering device in which a plurality of sputtering cathodes are provided respectively having targets created in accordance with the composition of a thin film intended to form a film on the treated substrate surface by being made to face the treated substrate disposed within a vacuum chamber capable of being maintained to a predetermined degree of vacuum.

In the multi-target sputtering device, a method is known in which film formation is performed while rotating a substrate and a substrate-supporting table that supports the substrate, in order to enhance the film thickness uniformity on the substrate surface due to the incidence of sputtered particles upon the substrate from the oblique direction (see, for example, Patent Document 1).

Further, in recent sputtering devices, in order to improve sputtering performance, an increase in input power at the time of sputtering has been contrived. Thereby, film formation can be performed in a shorter time, and thus an improvement in throughput can be realized.

### RELATED ART DOCUMENT

### Patent Document

Patent Document 1: Japanese Unexamined Patent Application, First Publication No. 2007-321238

### SUMMARY

### Problems to be Solved by the Invention

In sputtering devices for such applications however, it is required that the film thickness be thin and the film formation be performed so as to obtain a good film thickness in terms of uniformity, in a film-forming process of an LED, an optical film and the like.

In the case of a type which rotates a substrate as mentioned above, in order to further enhance the film thickness uniformity, it is preferable that the film formation time be sufficiently long for the rotation period of the substrate. However, since the film formation time is shortened with a reduction in the thickness and an increase in input power, there is a problem in that the film formation time is not sufficient for the rotation period of the substrate.

For example, when the sputtering film formation time is 1.5 seconds while the rotation period of the substrate is 1 second (60 rpm), the substrate is rotated 1.5 turns during the sputtering film formation time. In this case, the last 0.5 seconds of the sputtering film formation time of 1.5 seconds become a factor in causing film thickness non-uniformity, and thus the film thickness distribution is greatly impaired. In other words, since the substrate is rotated 540 degrees during the sputtering film formation time of 1.5 seconds, a non-uniform film thickness is formed in the surplus rotation (180 degrees) for one rotation of 360 degrees.

To address this problem, a method of improving the film thickness distribution by further increasing the rotation speed is considered. However, there is a problem in that an increase in power consumption of a film-forming device or a decrease in the life span of a rotating device occurs due to the increase in the rotation speed.

In addition, the processing chamber staying time per one substrate, which is directly linked to throughput, includes not only the sputtering film formation time, but also the time for which the rotation speed of the substrate is accelerated up to a predetermined rotation speed after the substrate is placed on the substrate-supporting table and the time for which it is decelerated. When attempts are made to increase the rotation speed, the acceleration time and the deceleration time also lengthen, and thus there is a problem in that throughput is deteriorated.

The present invention is contrived in view of such circumstances, and an object thereof is to provide a film-forming device and a film-forming method which are capable of achieving film thickness uniformity, suppressing power consumption at the time of sputtering, realizing an increase in the life span of driving unit that rotates a substrate-supporting table, and performing sputtering in a shorter time.

### Means for Solving the Problems

In order to achieve the above-mentioned object, the present invention provides the following means.

The present invention provides a film-forming device, including: a chamber in which a substrate is disposed, the substrate having a film to be formed thereon through sputtering film formation; a target, disposed within the chamber, which contains a material from which the film is formed; a substrate-supporting table disposed inside the chamber; driving unit that rotates the substrate-supporting table; a sputtering cathode on which the target is mounted and which causes sputtered particles to be incident on the substrate on the substrate-supporting table from an oblique direction; and a control unit that controls the driving unit by setting a rotation period so that a sputtering film formation time for which the substrate-supporting table is rotated at a predetermined rotation period is an integer multiple of a rotation period of the substrate-supporting table, the sputtering film formation time being required to form a film having a desired thickness.

In addition, it is preferable that the control unit control the driving unit so that an acceleration time and a deceleration time during acceleration until a rotation period of the substrate-supporting table reach a predetermined rotation period and during deceleration after termination of the film formation be equal to each other, the acceleration time and the deceleration time be set to be an integer multiple of the rotation period, and then the sputtering film formation be performed during the acceleration and the deceleration.

The present invention provides a film-forming method making use of a film-forming device, including a chamber in which a substrate is disposed, the substrate having a film to be formed thereon through sputtering film formation, a target, disposed within the chamber, which contains a material from which the film is formed, a substrate-supporting table disposed inside the chamber, driving unit that rotates the substrate-supporting table, and a sputtering cathode on which the target is mounted and which causes sputtered particles to be incident on the substrate on the substrate-supporting table from an oblique direction, the method including: controlling the driving unit by setting a rotation period so that a sputtering film formation time for which the substrate-supporting table is rotated at a predetermined rotation period is an integer multiple of a rotation period of the substrate-supporting table, the sputtering film formation time being required to form a film having a desired thickness.

In addition, it is preferable that the film-forming method further include setting a maximum rotation period, and setting a rotation period so that the rotation period not be longer than the maximum rotation period.

In addition, it is preferable that the film-forming method further include performing a setting so that an acceleration time and a deceleration time during acceleration until a rotation period of the substrate-supporting table reach a predetermined rotation period and during deceleration after termination of the film formation be equal to each other, and that the acceleration time and the deceleration time be set to be an integer multiple of the rotation period, and then performing the sputtering film formation during the acceleration and the deceleration.

### Advantageous Effects of Invention

According to the present invention, in the film-forming device including the sputtering cathode on which the target is mounted and which causes sputtered particles to be incident on the substrate on the substrate-supporting table from an oblique direction, it is possible to make the film thickness distribution more uniform by the configuration in which the control unit is included which controls the driving unit of the substrate-supporting table by setting a rotation period so that the sputtering film formation time required to form a film having a desired thickness is an integer multiple of a rotation period of the substrate-supporting table.

In addition, since the rotation speed of the substrate-supporting table decreases, it is possible to suppress power consumption, and to realize an increase in the life span of the device.

In addition, it is possible to further shorten the film formation time by performing the sputtering film formation during acceleration until the rotation period of the substrate-supporting table reaches a predetermined rotation period and during deceleration after the termination of the film formation.

### BRIEF DESCRIPTION OF THE DRAWINGS

FIG. 1 is a schematic cross-sectional view illustrating a film-forming device according to the invention.

FIG. 2 is a schematic plan view illustrating the film-forming device.

FIG. 3 is a graph illustrating a relationship between the film formation time and the rotation speed.

FIG. 4 is a graph illustrating a relationship between the film formation time and the rotation speed.

### DETAILED DESCRIPTION

Hereinafter, an embodiment of the invention will be described in detail with reference to the drawings. Meanwhile, the invention is not limited to the following embodiment, but various modifications can be made based on the technical spirit of the invention.

(Sputtering Device)

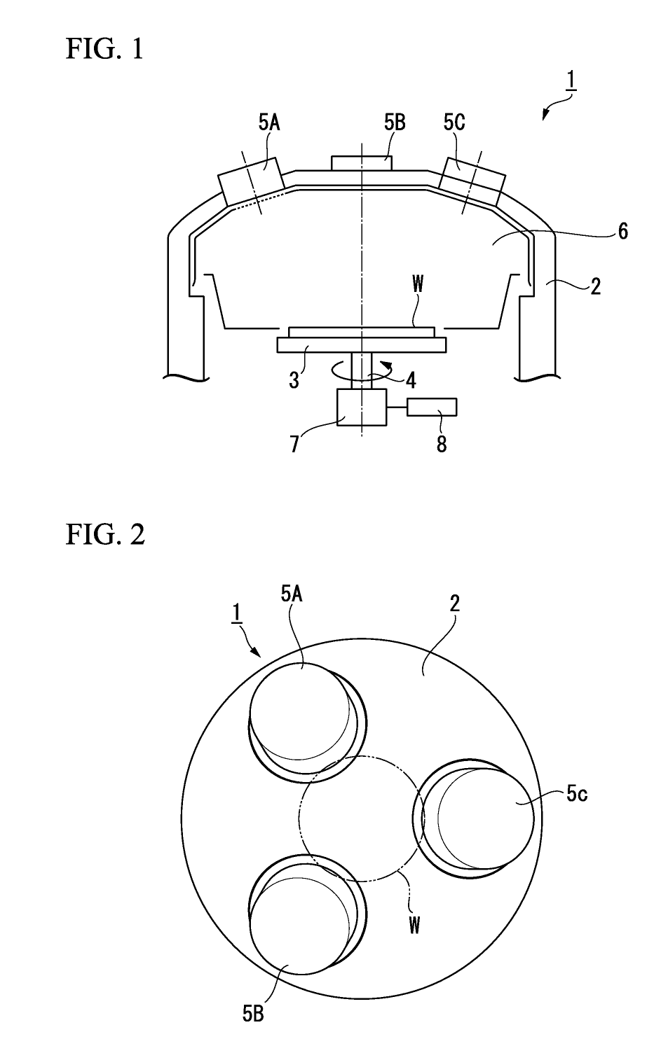

FIG. 1 is a schematic cross-sectional view illustrating a film-forming device 1 according to the present embodiment. In the present embodiment, the film-forming device 1 is configured as a magnetron sputtering device.

The film-forming device 1 includes a chamber 2 of which the inside can be hermetically sealed, a substrate-supporting table 3 disposed inside the vacuum chamber 2, driving unit 7 that rotates the substrate-supporting table 3 using a rotating shaft 4 as a shaft center, a plurality of (three sets in the present embodiment) sputtering cathodes 5A, 5B, and 5C disposed inside the vacuum chamber 2, and the like.

The vacuum chamber 2 is configured such that a processing chamber 6 is formed therein and the processing chamber 6 can be depressurized up to a predetermined degree of vacuum through vacuum exhaust unit (not shown). In addition, a gas introduction nozzle (not shown) for introducing process gas such as argon gas or reactive gas such as oxygen and nitrogen into the processing chamber 6 is installed at a predetermined position of the vacuum chamber 2.

The substrate-supporting table 3 is configured to be capable of heating a substrate W placed on the substrate-supporting table 3 to a predetermined temperature using temperature-adjusting unit (not shown). In addition, the substrate W is fixed to the substrate-supporting table 3 by, for example, an electrostatic chuck.

The rotating shaft 4 is configured to be capable of being rotated by the driving unit 7, which is a motor or the like. Thereby, a substrate rotating mechanism that rotates the substrate W around the center thereof is formed. A magnetic fluid seal is used for a shaft seal of the rotating shaft 4.

As shown in FIG. 2, in the upper portion of the vacuum chamber 2, the sputtering cathodes 5A to 5C are disposed at equiangular intervals on the concentric circle centered on the substrate W. These sputtering cathodes 5A to 5C are respectively and independently equipped with plasma-generating sources such as a high-frequency power source and a magnet mechanism for forming plasma within the processing chamber 6.

Targets made of an arbitrary material formed on the substrate W are respectively held in each of the sputtering cathodes 5A to 5C. Each of the sputtering cathodes 5A to 5C is installed at the chamber 2 while being inclined at a predetermined angle so that sputtered particles expelled from the targets by argon ions in plasma are incident from the oblique direction with respect to the normal direction of the substrate W.

The driving unit 7 is controlled by a control unit 8. The control unit 8 is configured to be capable of rotating the rotating shaft 4 at a predetermined rotation speed. That is, a user can rotate the substrate W at a desired rotation speed and rotation period.

The control unit 8 has a function of calculating the sputtering film formation time T (seconds) from the sputtering deposition rate determined by the specification or the like of the film-forming device 1 and the deposition film thickness a user desires.

Further, the control unit 8 has a function of determining the rotation period P (seconds) in accordance with the calculated sputtering time T. The term “rotation period P” herein is a time (seconds) required for the substrate-supporting table 3 to rotate once, and a value calculated by P=60/S when the rotation speed of the substrate-supporting table 3 is set to S rpm (rotation/min).

The control unit 8 controls the driving unit so that the sputtering film formation time T is an integer multiple of the rotation period P. That is, when the sputtering film formation time is set to T, the rotation period P is calculated as the following numerical formula (1). Here, n denotes an integer.

T=n×P (1)

That is, the rotation period P is calculated by the following numerical formula (2).

P=(1/n)×T (2)

The substrate-supporting table 3 (substrate W) is rotated exactly n times during the sputtering film formation time T by performing a control for rotating the substrate-supporting table 3 at the rotation speed S corresponding to the rotation period P calculated by such a method.

In other words, the rotation period P (rotation speed S) is determined so that the substrate-supporting table 3 is rotated exactly (360×n) degrees at a constant speed during the sputtering film formation time T. It should be understood that the time (sputtering film formation time T) for which the sputtering film formation is performed is also exactly controlled.

Considering the power consumption or the life span of the driving unit 7, it is preferable that the rotation speed S be slow (the rotation period P is long). That is, it is preferable that n be a small integer.

However, when the rotation period P is too long, that is, the rotation speed S is too slow, problems such as the film thickness uniformity and the vibration of a drive motor occur, and thus it is preferable that the maximum rotation period Pmax (lowest rotation speed) be set. When the calculated rotation period P is less than the maximum rotation period Pmax, a recalculation is performed so as not to exceed the maximum rotation period Pmax by sequentially increasing the value of n in the above-mentioned calculation formula.

On the other hand, it is preferable that the minimum rotation period Pmin (highest rotation speed) be set in accordance with the specification of the driving unit 7. When the rotation period P less than the minimum rotation period Pmin is calculated even in the case of n=1, a warning is displayed on a display device (not shown), and then processing is performed at the minimum rotation period Pmin

In addition, when the sputtering film formation time T can be predicted to some extent, a method may be used in which the number of rotations (integer n in the above-mentioned calculation formula) for the sputtering film formation time T is previously set.

For example, when the sputtering film formation time T can be predicted to be equal to or less than 60 seconds, and the sputtering film formation time is equal to or more than 1 second and less than 30 seconds, the control is performed so as to rotate the substrate-supporting table 3 once in the sputtering film formation time T. In addition, when the sputtering film formation time T is equal to or more than 30 seconds and equal to or less than 60 seconds, the control is performed so as to rotate the substrate-supporting table 3 twice in the sputtering film formation time T. It is possible to calculate the rotation period P (rotation speed S) more easily by preparing such a data table.

For example, when the sputtering film formation time T is calculated to be 50 seconds in the above-mentioned data table, the control is performed so as to rotate the substrate-supporting table 3 twice. That is, the rotation period P is calculated to be (50 seconds/2 rotations=)25 seconds.

In addition, when the substrate-supporting table 3 is rotated at a predetermined rotation speed S, time (acceleration time) during which the substrate-supporting table is accelerated up to a predetermined rotation speed S and time (deceleration time) during which it is decelerated are required during the actual time spent in the processing chamber.

In order to further shorten the time spent in the processing chamber, it is preferable that the sputtering film formation be also performed in the acceleration time and the deceleration time by the following method. That is, the sputtering film formation is also performed in the acceleration time and the deceleration time by performing the acceleration and the deceleration so as to make an accelerated velocity in the acceleration time and an accelerated velocity in the deceleration time constant, and to make the absolute values of the accelerated velocity in the acceleration time and the accelerated velocity in the deceleration time equal to each other.

The film thickness distribution during the acceleration deviates, but the deviation of the film thickness distribution during the deceleration complements it. Since the sputtering film formation can be performed even during the acceleration and the deceleration by the above-mentioned method, it is possible to shorten the time spent in the processing chamber without deteriorating the film thickness distribution. However, it is necessary that the acceleration time and the deceleration time be an integer multiple of the rotation period P of the rotation speed S.

### EXAMPLE

Hereinafter, the invention will be described in more detail by way of Examples, but the invention is not limited to these Examples.

### Example 1

In Example 1, a Cu film was formed using the film-forming device 1 shown in FIGS. 1 and 2. As the substrate W, a Si wafer of φ300 mm was used. In addition, a target of which the composition ratio of Cu was 99% and the diameter of the sputtering surface was φ125 mm was used. The film thickness of the Cu film to be formed was set to 1.5 μm.

First, the sputtering film formation time was calculated from the sputtering rate of the film-forming device 1, and the thickness of the Cu film to be formed. The sputtering film formation time was set to 1.5 seconds. When the substrate-supporting table 3 is rotated once for 1.5 seconds, the rotation period P becomes (( 1/1)×1.5=)1.5 seconds (40 rpm) from P=(1/n)×T.

When the film formation was performed under these conditions, the substrate-supporting table 3 was rotated exactly once in the film formation time of 1.5 seconds, and thus the film formation having a high uniformity of film thickness could be performed.

### Comparative Example 1

The film formation was performed by a method similar to Example 1 except that the rotation period P (rotation speed) was not controlled. The rotation period P was set to 1 second (rotation speed of 60 rpm).

Since the film-forming device 1 is the same, the sputtering film formation time T is 1.5 seconds. When the film formation was performed in this condition, the substrate-supporting table 3 was rotated 1.5 times in the film formation time of 1.5 seconds, and thus the film thickness distribution was not greatly impaired.

As stated above, when Example 1 and Comparative Example 1 were compared to each other, the film formation having a high uniformity of film thickness could be realized in Example 1 in the same sputtering film formation time T.

### Example 2

In Example 2, a Cu film was formed using the film-forming device 1 shown in FIG. 1. As the substrate W, a Si wafer of φ300 mm was used. In addition, a target of which the composition ratio of Cu was 99% and the diameter of the sputtering surface was φ125 mm was used. The film thickness of the Cu film to be formed was set to 180 μm. That is, the thickness of the Cu film was further increased than in Example 1.

In addition, the minimum rotation period was set to 1 second (60 rpm) and the maximum rotation period was set to 60 seconds (1 rpm), and then the following data table was prepared.

1≦T≦10 (seconds): n=1 (rotation)

10<T≦20 (seconds): n=2 (rotations)

20<T≦60 (seconds): n=3 (rotations)

60<T≦120 (seconds): n=4 (rotations)

120<T≦300 (seconds): n=5 (rotations)

First, the sputtering film formation time was calculated from the sputtering rate of the film-forming device 1, and the thickness of the Cu film to be formed. The sputtering film formation time was set to 120 seconds.

From the above-mentioned data table, the number of rotations of the substrate-supporting table 3 rotated during the sputtering film formation time T is 4. The rotation period P is set to ((¼)×120=) 30 seconds from the above-mentioned formula of P=(1/n)×T.

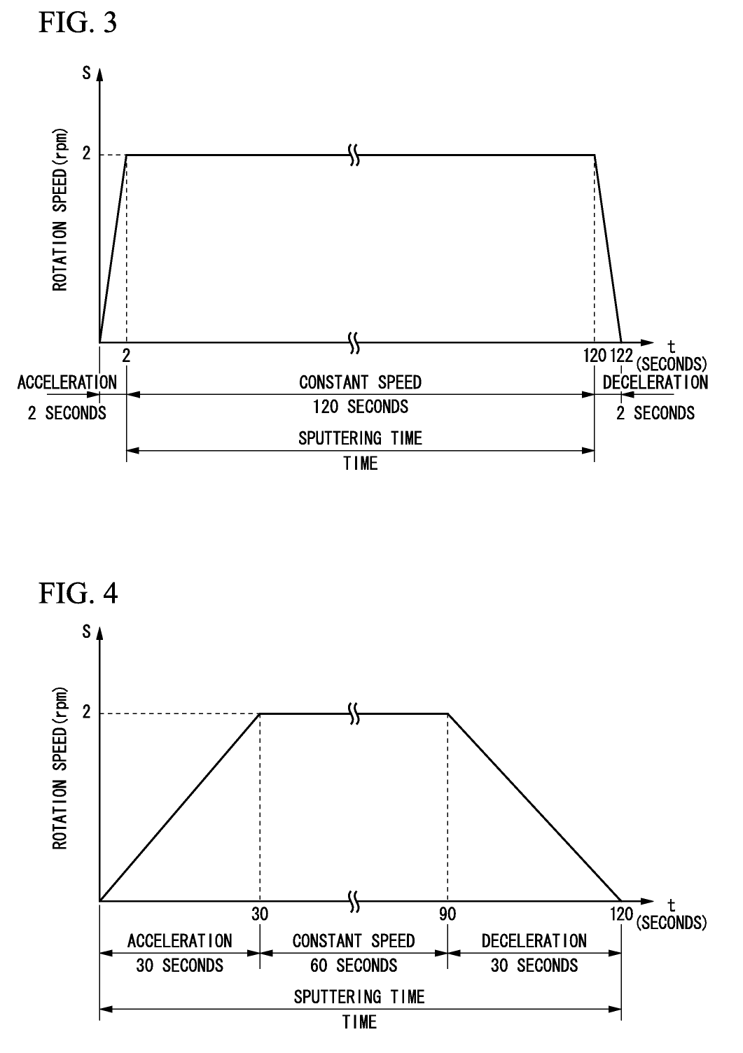

When rotation of the rotation period P=30 seconds was converted to the rotation speed, the rotation is 2 rpm (rotation/min) In the film-forming device used in the present Example, the time required for acceleration up to the rotation speed of 2 rpm and the time required until the substrate-supporting table 3 was stopped from 2 rpm were 2 seconds, respectively, and thus the time spent in the processing chamber for each one film formation was (120+4=) 124 seconds as shown in FIG. 3.

### Example 3

The film formation was performed by a method similar to Example 2 except that the sputtering film formation was performed even during the acceleration of the substrate-supporting table 3 and during the deceleration of the substrate-supporting table 3.

The time required to accelerate the substrate-supporting table 3 up to 2 rpm was 2 seconds. However, since it was necessary that the acceleration time and the deceleration time be set to be an integer multiple of the rotation period P=30 seconds at least 2 rpm, the acceleration time and the deceleration time were set to 30 seconds, respectively.

In addition, the acceleration and the deceleration were performed so as to make the accelerated velocity in the acceleration and the accelerated velocity in the deceleration constant, and make the absolute values of the accelerated velocity in the acceleration and the accelerated velocity in the deceleration equal to each other.

As shown in FIG. 4, the sputtering film formation performed in the acceleration and the deceleration is equivalent to the sputtering film formation of 60 seconds in the sputtering film formation at the rotation speed of 2 rpm. Consequently, the calculated sputtering film formation time can be shortened from 120 seconds to 60 seconds. Consequently, the processing chamber staying time per one film formation is 60+60=120 seconds.

### Comparative Example 2

Film formation was performed by a conventionally known method. The film formation time was 120 seconds, as in the case of Example. On the other hand, the stage rotation speed was set to 60 rpm (rotation period of 1 second). In addition, the time required to accelerate the substrate-supporting table up to 60 rpm was 30 seconds, and the time required to stop it from 60 rpm was also 30 seconds.

In this case, the stage rotation speed was fast enough, and thus there were no problems in terms of the film thickness uniformity. The processing chamber staying time per one film formation was (120+30×2=) 180 seconds.

When Example 2 and Comparative Example 2 were compared to each other, the processing chamber staying time per one film formation was (180 seconds−120 seconds=) 60 seconds, and it took a considerable time in Comparative Example 2. This was due to the difference between the acceleration time of the substrate-supporting table 3 up to a predetermined rotation speed and the deceleration time for stopping the substrate-supporting table 3. In addition, in Example 2, the substrate-supporting table 3 was controlled so as to be exactly rotated twice at the sputtering time T. Thereby, there were no problems in terms of the film thickness uniformity in spite of the rotation speed being slower than in Comparative Example 2.

As in Example 3, it was possible to further shorten the processing time of 4 seconds with respect to Example 2 by performing the sputtering film formation even in the acceleration and the deceleration.

### REFERENCE SIGNS LIST

W: SUBSTRATE
T: SPUTTERING FILM FORMATION TIME
P: ROTATION PERIOD
1: FILM-FORMING DEVICE
2: CHAMBER
3: SUBSTRATE-SUPPORTING TABLE
4: ROTATING SHAFT
5: SPUTTERING CATHODE
6: PROCESSING CHAMBER
7: DRIVING UNIT

What is claimed is:

1. A film-forming device comprising:
a chamber in which a substrate is disposed, the substrate having a film to be formed thereon through sputtering film formation;
a target, disposed within the chamber, which contains a material from which the film is formed;
a substrate-supporting table disposed inside the chamber;
a driving unit that rotates the substrate-supporting table;
a sputtering cathode on which the target is mounted and which causes sputtered particles to be incident on the substrate on the substrate-supporting table from an oblique direction; and
a control unit that controls the driving unit by setting a rotation period so that a sputtering film formation time for which the substrate-supporting table is rotated at a predetermined rotation period is an integer multiple of a rotation period of the substrate-supporting table, the sputtering film formation time being required to form a film having a desired thickness.

2. The film-forming device according to claim 1, wherein the control unit controls the driving unit so that an acceleration time and a deceleration time during acceleration until a rotation period of the substrate-supporting table reaches a predetermined rotation period and during deceleration after termination of the film formation are equal to each other, the acceleration time and the deceleration time are set to be an integer multiple of the rotation period, and then the sputtering film formation is performed during the acceleration and the deceleration.

3. A film-forming method making use of a film-forming device, including a chamber in which a substrate is disposed, the substrate having a film to be formed thereon through sputtering film formation, a target, disposed within the chamber, which contains a material from which the film is formed, a substrate-supporting table disposed inside the chamber, driving unit that rotates the substrate-supporting table, and a sputtering cathode on which the target is mounted and which causes sputtered particles to be incident on the substrate on the substrate-supporting table from an oblique direction, the method comprising:
controlling the driving unit by setting a rotation period so that a sputtering film formation time for which the substrate-supporting table is rotated at a predetermined rotation period is an integer multiple of a rotation period of the substrate-supporting table, the sputtering film formation time being required to form a film having a desired thickness.

4. The film-forming method according to claim 3, further comprising setting a maximum rotation period, and setting a rotation period so that the rotation period is not longer than the maximum rotation period.

5. The film-forming method according to claim 3, further comprising performing a setting so that an acceleration time and a deceleration time during acceleration until a rotation period of the substrate-supporting table reaches a predetermined rotation period and during deceleration after termination of the film formation are equal to each other, and that the acceleration time and the deceleration time are set to be an integer multiple of the rotation period, and then performing the sputtering film formation during the acceleration and the deceleration.

6. The film-forming method according to claim 4, further comprising performing a setting so that an acceleration time and a deceleration time during acceleration until a rotation period of the substrate-supporting table reaches a predetermined rotation period and during deceleration after termination of the film formation are equal to each other, and that the acceleration time and the deceleration time are set to be an integer multiple of the rotation period, and then performing the sputtering film formation during the acceleration and the deceleration.
